(19) United States
(12) Patent Application Publication
(10) Pub. No.: US 2026/0123530 A1
(43) Pub. Date: Apr. 30, 2026

(54) METHOD FOR FORMING THROUGH VIAS IN A DIE STACK

(71) Applicant: Applied Materials, Inc., Santa Clara, CA (US)

(72) Inventors: Sony Varghese, Manchester, MA (US); Niranjan R. Khasgiwale, San Jose, CA (US)

(21) Appl. No.: 18/931,459

(22) Filed: Oct. 30, 2024

(51) Int. Cl. H01L 25/065; H01L 21/66; H01L 23/00; H01L 23/498; H01L 25/00

(52) U.S. Cl. CPC H10W 90/00; H10P 74/238; H10W 70/635; H10W 90/735; H10W 90/736

(57) ABSTRACT

A method includes forming a plurality of dies on one or more first substrates. The method further includes stacking multiple dies of the plurality of dies on a second substrate to form a die stack. The method further includes forming a through-via in the die stack. The through-via electrically couples each of the multiple dies of the die stack.

### TECHNICAL FIELD

The instant specification generally relates to electronic device fabrication. More specifically, the instant specification relates to forming through vias in a die stack.

### BACKGROUND

Semiconductor devices (i.e., dies) can be stacked to form high bandwidth memory (HBM). Through-silicon vias (TSVs, e.g., through-vias) are formed in the semiconductor devices to electrically couple each of the devices in a stack.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In accordance with at least one embodiment, a method includes forming a plurality of dies on one or more first substrates. The method further includes stacking multiple dies of the plurality of dies on a second substrate to form a die stack. The method further includes forming a through-via in the die stack. The through-via electrically couples each of the multiple dies of the die stack.

In accordance with at least one embodiment, a system includes a memory and a processing device operatively coupled with the memory. The processing device is configured to cause a plurality of dies to be formed on one or more first substrates. The processing device is further configured to cause multiple dies of the plurality of dies to be stacked on a second substrate to form a die stack. The processing device is further configured to cause a through-via to be formed in the die stack. The through-via electrically couples each of the multiple dies of the die stack.

In accordance with at least one embodiment, a manufacturing system includes one or more process tools. The one or more process tools are configured to form a plurality of dies on one or more first substrates. The one or more process tools are further configured to stack multiple dies of the plurality of dies on a second substrate to form a die stack. The one or more process tools are further configured to form a through-via in the die stack. The through-via electrically couples each of the multiple dies of the die stack.

### BRIEF DESCRIPTION OF THE DRAWINGS

Aspects and implementations of the present disclosure will be understood more fully from the detailed description given below and from the accompanying drawings, which are intended to illustrate aspects and implementations by way of example and not limitation.

FIG. 1 is a flow chart of an example method for forming die stacks, in accordance with some embodiments.

FIGS. 2A-M are simplified cutaway schematic views depicting the formation of die stacks, in accordance with some embodiments.

FIG. 3 is a flow chart of an example method for forming a through-via in a die stack, in accordance with some embodiments.

FIG. 4 is a block diagram illustrating a computer system, in accordance with some embodiments.

### DETAILED DESCRIPTION

To form high bandwidth memory (HBM) devices, such as dynamic random access memory (DRAM) devices, semiconductor dies are stacked one on top of the other to form a device package (e.g., a die stack). Through-silicon vias (TSVs) are used to electrically couple each of the stacked semiconductor dies. Some methods of forming packages include forming TSVs in each of the dies during manufacturing of the individual dies. Not all manufactured dies may pass a quality test, meaning some of the dies are non-yielding dies. Thus, TSVs may be formed on non-yielding dies, which may be a waste of time and resources. Moreover, the manufactured dies may be individually stacked. During stacking, there may be misalignment between dies. For example, stacked dies may be misaligned in the XY plane and/or rotationally misaligned. More than a threshold amount of misalignment can cause the TSVs formed in the individual dies not to line up with one another, therefore rendering the stack of dies unusable. To correctly align the dies, extra time may be taken during assembly, resulting in slow processes and low throughput.

Alternate conventional methods of forming stacked die packages include stacking multiple substrates (e.g., wafers, etc.) with dies formed thereon. Assembling stacked die packages in this manner may overcome the above-described issues regarding die alignment. However, because die yield on a substrate is often random, non-functional dies may be stacked with functional dies, causing the stacked die package to be non-functional. For example, when a non-functional die on a first substrate is stacked with one or more functional dies on one or more second substrates, the assembled stacked die package becomes non-functional because of the non-functional die. Therefore, stacking multiple substrates with dies formed thereon may result in low overall throughput.

Embodiments of the present disclosure address the above-described problems and/or shortcomings of conventional solutions by providing a method for forming a die stack which includes forming a through-via in the stack after stacking. In some embodiments, a through-via is formed on a reconstituted die that may have alignment errors that may limit patterning using traditional methods. In some embodiments, known “good” dies are used to form die stacks lacking a through-via. A through-via may be formed after the stacking.

In some embodiments, a method includes forming a plurality of dies (e.g., semiconductor devices, etc.) on one or more first substrates. The plurality of dies may be formed using any of a variety of known methods and/or techniques, etc. Each of the formed dies may have a connective pad for electrically coupling the die to one or more other dies, such as by a through after the dies are stacked. When initially formed, each of the plurality of dies may not have a through-via. In some embodiments, after formation of the plurality of dies, the plurality of dies may be tested to identify a subset of the dies that meet a quality criterion. For example, the dies formed on a substrate may be tested for functionality. Functional and nonfunctional dies may be identified, such as by a substrate-level die map. In some embodiments, the one or more first substrates are diced to separate the plurality of dies. Dies that were identified as meeting the quality criterion (e.g., functional dies) may be selected. In some embodiments, the selected dies are stacked on a second substrate (e.g., a carrier substrate) to form a die stack. A die stack may be formed with multiple dies. For example, two or more dies (e.g., four dies) may be stacked to form a die stack. Multiple die stacks may be formed on the second substrate, each die stack separated by one or more gaps. In some embodiments, the one or more gaps are filled with a filler. A mask layer may be deposited on top of the filler and the die stacks. The mask layer may be patterned, such as for forming a through-via in each of the die stacks. In some embodiments, a through-via is formed in each of the die stacks according to the patterned mask layer. The through-vias may electrically couple each of the multiple dies of a die stack. After the through-vias are formed, the second substrate may be diced to separated each of the die stacks.

Aspects and implementations of the present disclosure result in technological advantages over other approaches. For example, alignment issues that can adversely affect previous approaches to forming die stacks can be avoided by forming through-vias after forming the die stacks rather than before forming the die stacks. Less time and expense may therefore be used to align dies in a stack, according to some embodiments. In another example, issues concerning low yield of some previous approaches (such as when substrates having dies formed thereon are stacked, etc.) can also be avoided by testing dies before stacking. Fewer non-functional die stacks may therefore be formed, according to some embodiments. Therefore, the present disclosure can decrease the time and expense for producing semiconductor die stacks and improve system throughput accordingly.

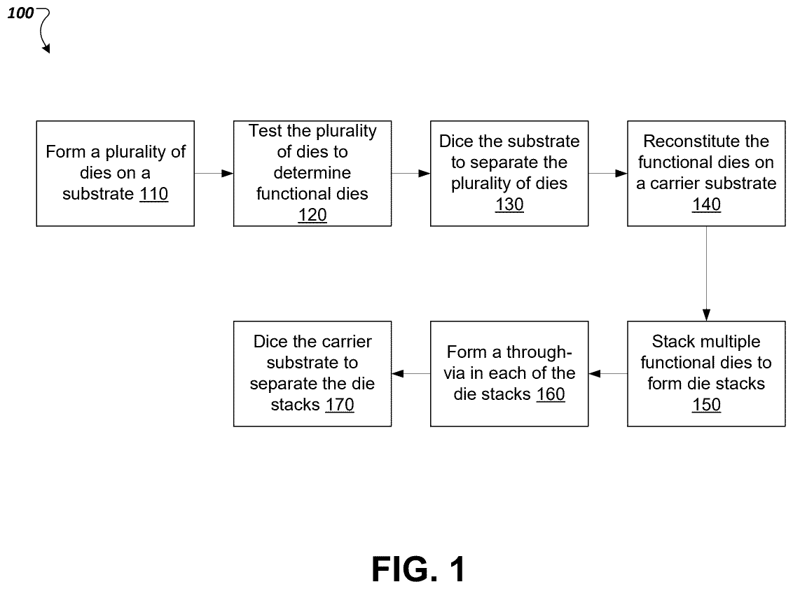

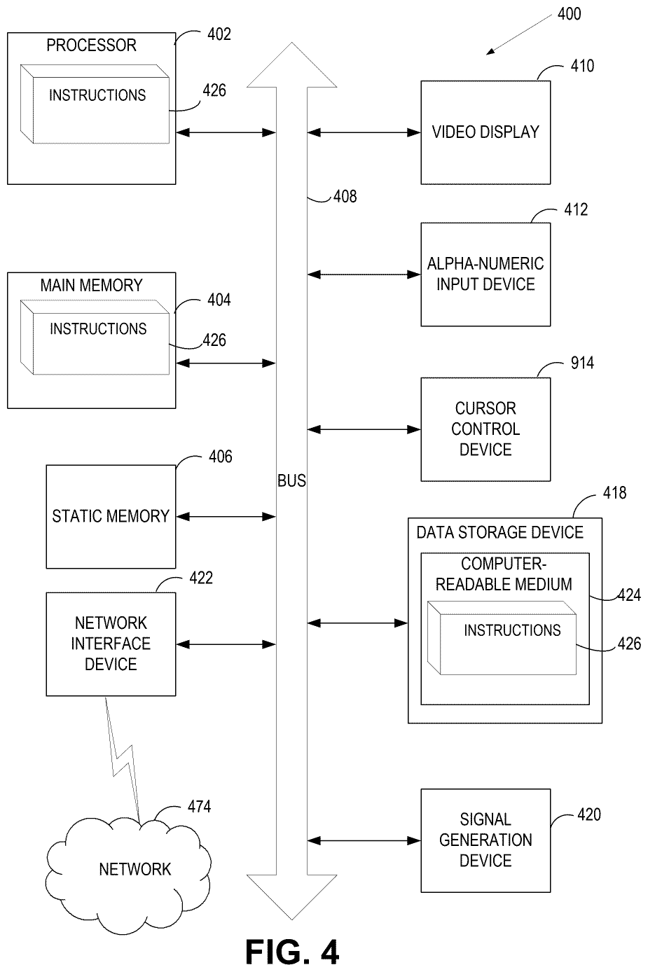

FIG. 1 is a flow chart of an example method 100 for forming die stacks, in accordance with some embodiments. The method 100 may be performed by a system that may include hardware (circuitry, dedicated logic, etc.), computer-readable instructions (run on a general purpose computer system or a dedicated machine), or a combination of both. In an illustrative example, method 100 may be performed by a manufacturing system that includes one or more process tools configured to perform method 100. The manufacturing system may be controlled, such as by computer system 400 described herein below with respect to FIG. 4. It should be noted that blocks depicted in FIG. 1 could be performed simultaneously or in a different order than that depicted.

At block 110, a plurality of dies are formed on a substrate. In some embodiments, the plurality of dies are formed on one or more substrates. For example, dies may be formed on multiple substrates. The dies may be semiconductor devices, etc. The dies may be formed using one or more techniques known in the art, such as one or more deposition, etch, and/or lithography processes, etc.

At block 120, the plurality of dies are tested to determine functional dies. A functional die may be a die that meets a quality criterion. In some embodiments, dies are tested while on the substrate. For example, a probe may be used to test each of the dies formed on a substrate. In some embodiments, a die map may be formed based on the testing. The die map may indicate which of the dies formed on the substrate are functional and which dies are non-functional. The die map may indicate the locations of the functional and/or non-functional dies.

At block 130, the substrate is diced to separate the plurality of formed dies. In some embodiments, dicing the substrate includes cutting the substrate into multiple pieces, where each piece includes a formed die. The tested non-functional dies may be discarded, such as based on the constructed die map.

At block 140, the functional dies are reconstituted on a carrier substrate. In some embodiments, the functional dies are selected from the dicing operation (at block 130). At least some of the functional dies are bonded to the carrier substrate to form a first layer of dies. At block 150, multiple functional dies are stacked (e.g., on top of the first layer of dies) to form die stacks. Each of the die stacks may include multiple functional dies, such as two or more dies, three or more dies, four or more dies, etc. In some embodiments, the die stacks are made up of four dies.

At block 160, a through-via is formed in each of the die stacks. Forming a through-via may include patterning a mask layer (e.g., such as by digital lithography, etc.) and performing an etch operation (e.g., an anisotropic etch operation, etc.) to form a via hole. The via hole may extend through each of the dies in the die stack. The via hole may be filled with a conductive metal, such as copper. The through-vias may electrically couple each of the dies in a particular die stack. Digital lithography may enable optimization of the patterning process to address translational and/or rotational errors that might be introduced during the stacking process of each individual die. An associated algorithm may be used to calculate and estimate one or more x,y coordinates and/or angle of rotation that may increase the probability of the TSV passing through all the dies in the stack.

At block 170, the carrier substrate is diced to separate the die stacks. In some embodiments, the die stacks are separated from the carrier substrate after the dicing. One or more die stacks may be stacked on top of one another to form a multi-stack die stack. For example, a die stack of four dies may be stacked on top of another die stack of four dies, forming a multi-stack die stack of eight dies. In some embodiments,

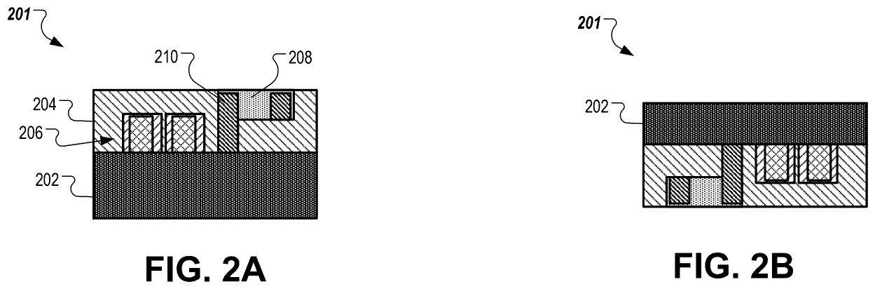

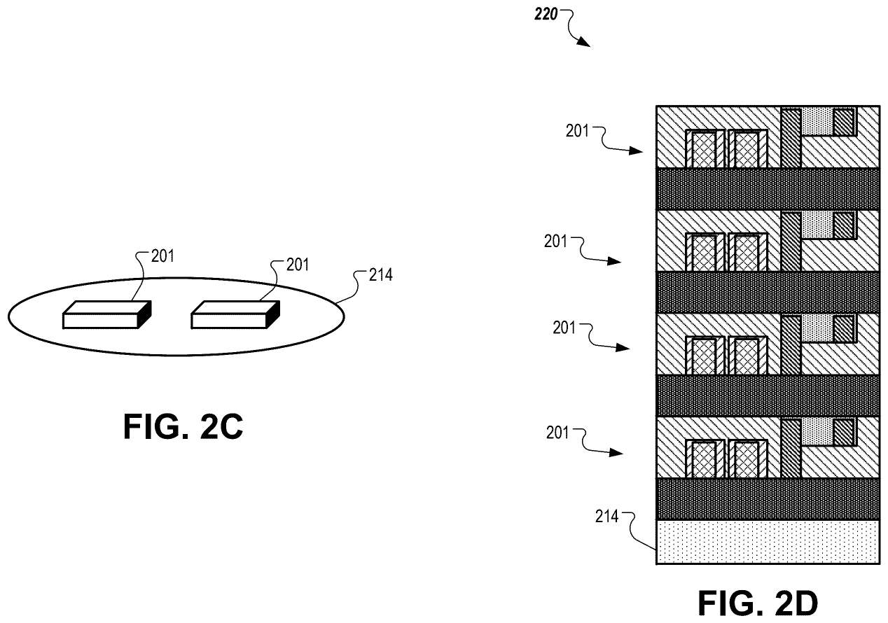

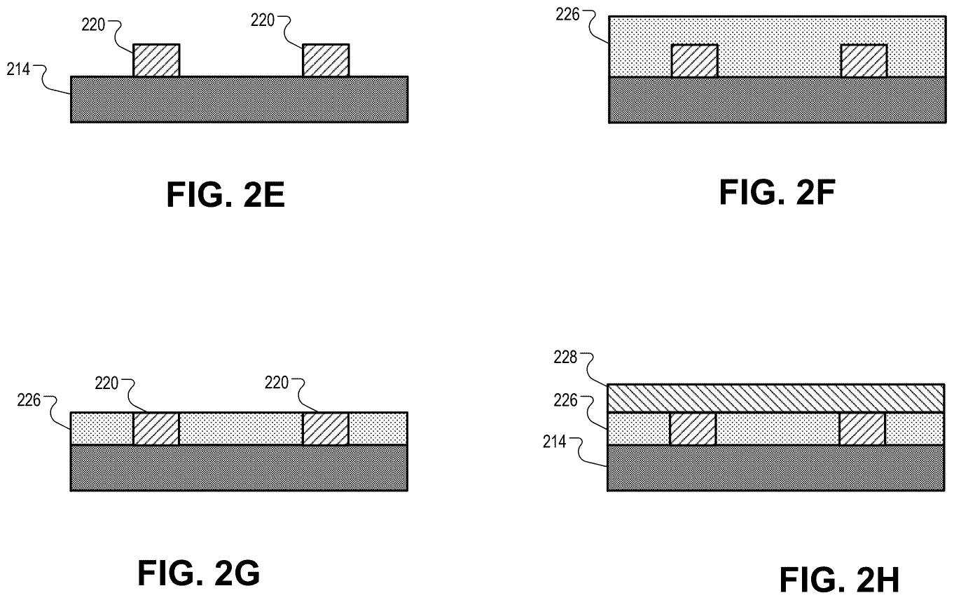

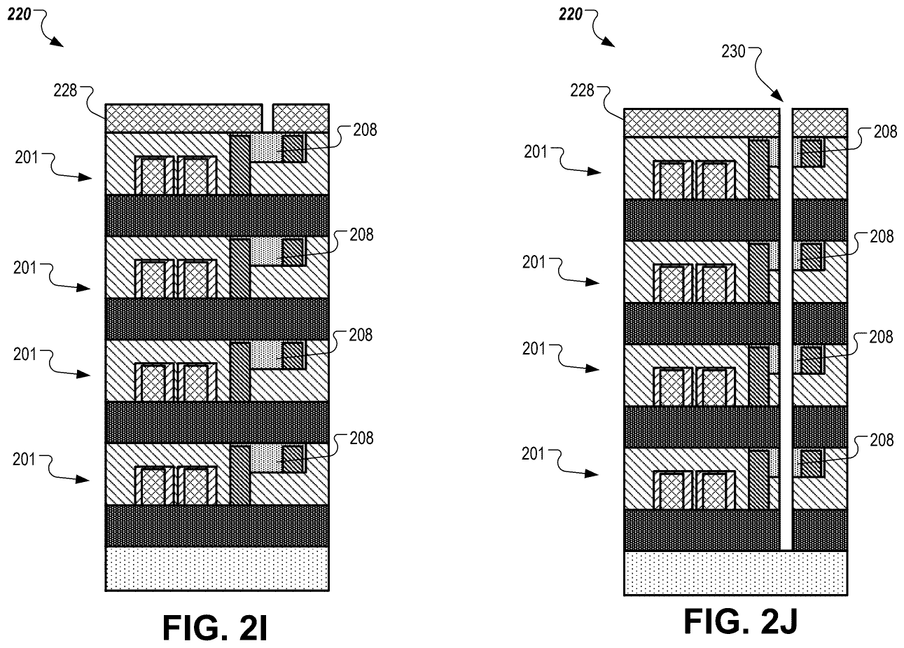

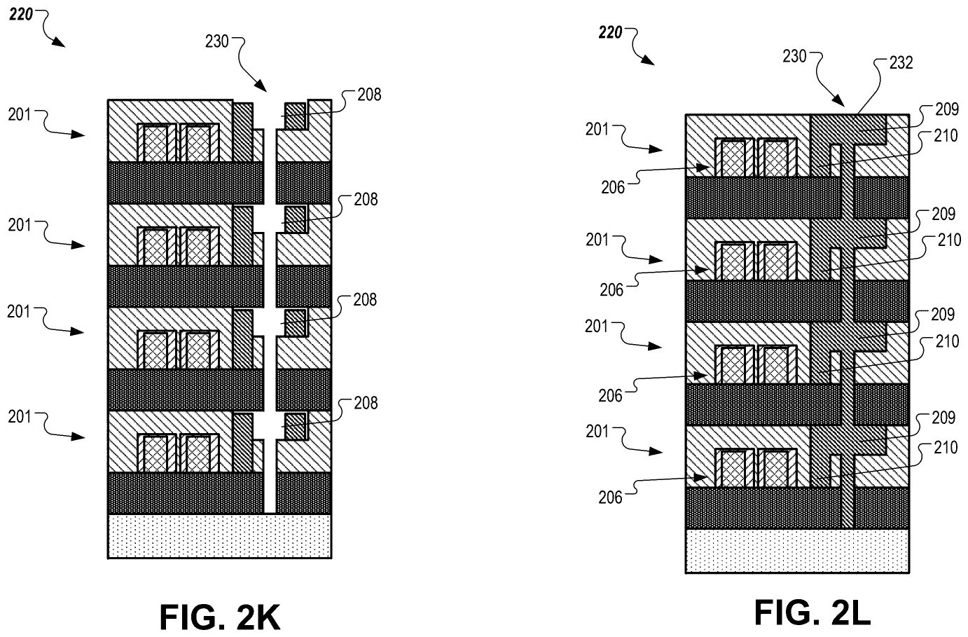

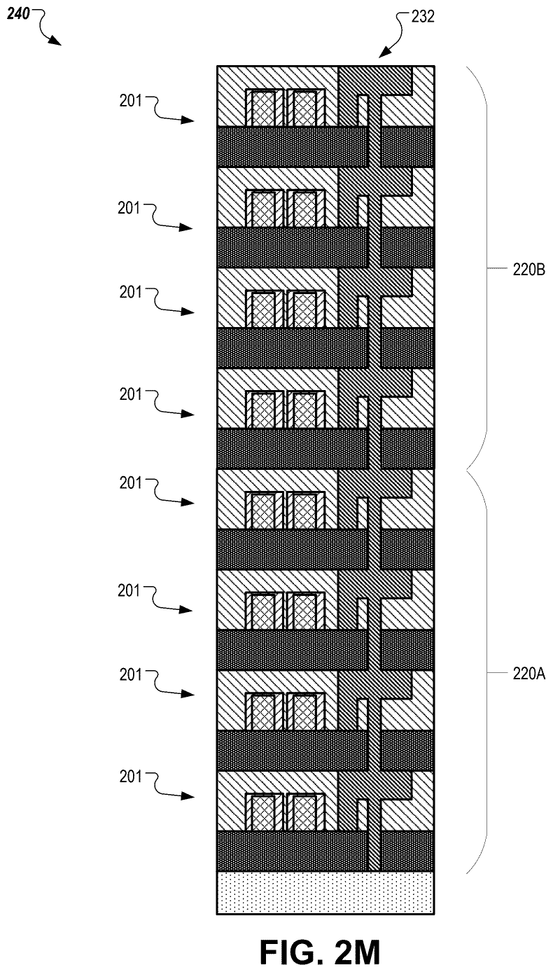

FIGS. 2A-M are simplified cutaway schematic views depicting the formation of die stacks, in accordance with some embodiments. The formation of die stacks may be accomplished using a manufacturing system having one or more process tools. Each of the operations described herein for forming die stacks may be performed using one or more process tools, such as process chambers, etc.

Referring to FIG. 2A, a cutaway schematic view of a singular die 201 is shown. In some embodiments, die 201 was formed on a substrate and tested for functionality. The die 201 may have tested positive for functionality. In some embodiments, the substrate upon which die 201 was formed may have been diced to separate die 201 from the other dies on the substrate, etc.

In some embodiments, die 201 includes a base layer 202 and an upper layer 204. Base layer 202 and/or upper layer 204 may comprise silicon. For example, base layer 202 may be a silicon oxide layer and upper layer 204 may be a silicon nitride layer. In some embodiments, base layer 202 and/or upper layer 204 are dielectric layers. In some embodiments, one or more components 206 are formed in the upper layer 204. The components 206 may be electrically coupled to a trace 210. In some embodiments, a sacrificial layer 208 is formed in the layer 204. The sacrificial layer 208 may be formed on an upper portion of the layer 204. The sacrificial layer 208 may be made up of a material such as silicon dioxide, polyimide, silicon (e.g., polycrystalline silicon, amorphous silicon, etc.), organic polymer, or silicon nitride, etc. Die 201 may have a height between approximately 20 microns and approximately 30 microns.

Referring to FIG. 2B, die 201 may undergo a thinning operation. In some embodiments, die 201 may be inverted and bonded to a carrier substrate for the thinning operation. The die 201 may be bonded to the carrier substrate in an upside-down orientation. The thinning operation may include thinning the base layer 202. For example, the thickness of the base layer 202 may be reduced. The thinning operation may be performed using chemical etchants and/or mechanical tools to reduce the thickness of base layer 202. In some embodiments, after the thinning operation, the die 201 is un-bonded from the carrier substrate.

Referring to FIG. 2C, dies 201 may be bonded to a carrier substrate 214. Dies 201 may be bonded to the carrier substrate 214 in a right-side-up orientation (e.g., as shown in FIG. 2A). Dies 201 bonded to the carrier substrate 214 may be a bottom die in a die stack. In some embodiments, multiple die stacks are formed on the carrier substrate 214. In some embodiments, dies 201 are bonded to the carrier substrate 214 such that there are gaps formed between the dies 201. The dies 201 may be bonded to the carrier substrate 214 using a bonding layer (not illustrated).

Referring to FIG. 2D, a die stack 220 is shown. In some embodiments, dies 201 are stacked on top of one another on the carrier substrate 214. For example, a first die 201 (e.g., a bottom die) may be bonded to the carrier substrate 214, a second die 201 may be bonded to the first die, a third die 201 may be bonded to the second die, and a fourth die 201 may be bonded to the third die. In some embodiments, the stacked dies of the die stack 220 are bonded to one another, such as by a fusion bond. In some embodiments, a die stack 220 includes up to four dies 201. In some embodiments, the dies 201 are stacked after performance of the thinning operation described above with respect to FIG. 2C. For example, the thinning operation may be performed with respect to each of the dies 201 before the stacking. In some embodiments, each of the dies 201 may be stacked with a misalignment with respect to one another, such as an XY misalignment and/or a rotational misalignment. Die stack 220 may have a height between approximately 80 microns and approximately 120 microns.

Referring to FIG. 2E, multiple die stacks 220 may be formed on the carrier substrate 214. The die stacks 220 may be formed so that there are one or more gaps between the die stacks 220. Referring to FIG. 2F, a gap fill 226 may be deposited to fill the gaps between the die stacks 220. The gap fill may be a polyimide material or an oxide material. The gap fill 226 may be deposited to fill the gaps and/or to cover each of the die stacks 220. Referring to FIG. 2G, a planarization process may be performed to form a substantially planar top surface. The planarization process may be performed to remove a portion of the gap fill 226. Removal of a portion of the gap fill 226 may planarize the top surface of the gap fill 226 and the die stacks 220. In some embodiments, the planarization process is performed so that the top surface of the gap fill 226 and the top surfaces of the die stacks 220 form a substantially planar top surface. The planarization process may be performed using chemical etchants, chemical polishers, and/or mechanical tools (e.g., mechanical planers, mechanical polishers, etc.). Referring to FIG. 2H, a mask layer 228 may be deposited on top of the gap fill 226 and/or the die stacks 220. The mask layer may be a hard layer such as silicon dioxide, molybdenum silicide, a metal fil, or a photo-sensitive resist, etc. In some embodiments, the mask layer 228 covers each of the die stacks 220 and the gap fill 226. The mask layer 228 may extend from edge-to-edge of the carrier substrate 214.

Referring to FIG. 2I, the mask layer 228 may be patterned, such as by photolithography (e.g., digital lithography, etc.). The mask layer 228 may be patterned to form an opening in the mask layer 228 over the sacrificial layers 208. Referring to FIG. 2J, a through-via hole 230 is formed through each of the sacrificial layers 208 of the dies 201. In some embodiments, the hole 230 is formed by performance of an anisotropic etch process. One or more etchants may be introduced to the die stack. The etchants may remove portions of the sacrificial layers 208 and one or more other layers of the dies 201 to form the hole 230. The hole 230 may extend from the top die 201 to the bottom die 201. In some embodiments, the sacrificial layers 208 each have a footprint that is larger than the diameter of the hole 230. Because the footprint of the each of the sacrificial layers 208 is larger than the diameter of the hole 230, the hole 230 may pass through the sacrificial layers 208 even with up to a threshold amount of misalignment between the dies 201.

Referring to FIG. 2K, each of the sacrificial layers 208 may be selectively etched to form voids in each of the dies 201. In some embodiments, an etchant is introduced into the hole 230 and the sacrificial layers 208 may be selectively etched. For example, the etchant may etch away the sacrificial layers 208 without etching the other layers of the dies 201. In some embodiments, selectively etching the sacrificial layers 208 forms a continuous void within the die stack 220.

Referring to FIG. 2L, the void left by the selective etching of the sacrificial layers 208, including the hole 230, is filled with an electrically conductive material, such as metal. The metal may be copper, a tungsten alloy, or another suitable metal, etc. The filling of the voids and the hole 230 with metal may form a through-via 232 to electrically couple each of the dies 201. In some embodiments, filling the void with metal forms connective pads 209 for each of the dies 201. Each of the connective pads 209 may electrically couple the traces 210 and the components 206. In some embodiments, the connective pads 209 have a footprint larger than the through-via 232 so that the connective pads 209 can be connected by the through-via 232 even if there is up to a threshold amount of misalignment between dies 201. After the through-via 232 is formed in the die stack, the carrier substrate may be diced to separate each of the multiple die stacks.

Referring to FIG. 2M, one or more additional die stacks may be stacked one on top of the other to form a multi-stack die stack 240. In some embodiments, a die stack 220B is stacked on top of a die stack 220A. Further die stacks 220 may be stacked on top of die stack 220B, in some embodiments. The die stacks 220A and 220B may both be tested for functionality before die stack 220B is stacked on top of die stack 220A. The die stack 220A may include multiple dies 201 and the die stack 220B may include multiple dies 201. In some embodiments, the die stack 220A includes four stacked dies 201 and the die stack 220B includes four stacked dies 201. Stacking die stack 220B on top of die stack 220A may form a multi-stack die stack 240 having eight stacked dies. In some embodiments, the through-via 232 extends through all the dies 201 of the multi-stack die stack 240. For example, the through-via 232 extends through all dies 201 of die stack 220B and all dies 201 of die stack 220A. The lower portion of through-via 232 corresponding to die stack 220A and the upper portion of through-via 232 corresponding to die stack 220B may be formed separately but may nonetheless be electrically coupled and form a single through-via 232 when the two die stacks are stacked.

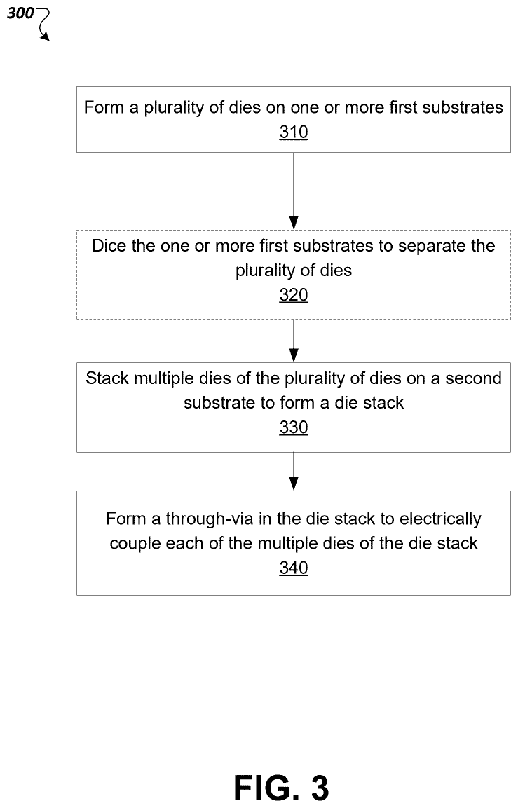

FIG. 3 is a flow chart of an example method 300 for forming a through-via in a die stack, in accordance with some embodiments. The method 300 may be performed by a system that may include hardware (circuitry, dedicated logic, etc.), computer-readable instructions (run on a general purpose computer system or a dedicated machine), or a combination of both. In an illustrative example, method 300 may be performed by a manufacturing system that includes one or more process tools configured to perform method 300. The manufacturing system may be controlled, such as by computer system 400 described herein below with respect to FIG. 4. It should be noted that blocks depicted in FIG. 3 could be performed simultaneously or in a different order than that depicted.

At block 310, a plurality of dies are formed on one or more first substrates. Each of the plurality of dies may be a semiconductor device, such as a memory device, etc. In some embodiments, the plurality of dies are formed on multiple substrates. For example, a first portion of the plurality of dies may be formed on one substrate, and a second portion of the plurality of dies may be formed on another substrate, etc. The dies may be formed using one or more techniques known in the art, such as one or more deposition, etch, and/or lithography processes, etc. Once the dies are formed, each of the plurality of dies may be tested for functionality. Functional dies and non-functional dies may be identified on the one or more first substrates.

At block 320, the one or more first substrates are diced to separate the plurality of dies. In some embodiments, dicing the substrate includes cutting the substrate into multiple pieces, where each piece includes a formed die. The tested non-functional dies may be discarded.

At block 330, multiple dies of the plurality of dies are stacked on a second substrate to form a die stack. The second substrate may be a carrier substrate, etc. In some embodiments, the multiple dies which are stacked are selected from the tested functional dies. The multiple dies may be stacked with an offset, such as an XY offset or a rotational offset.

At block 340, a through-via is formed in the die stack to electrically couple each of the multiple dies of the die stack. In some embodiments, the through-via is formed by forming a hole through sacrificial layers of each of the dies. The sacrificial layers may be larger in size than the diameter of the formed hole so that up to a threshold amount of offset of the dies in the die stack does not adversely affect formation of the trough-via. The sacrificial layers may be exhumed and replaced with a conductive material, such as metal (e.g., copper, tungsten alloy, etc.). The through-via may electrically couple each of the dies. After formation of the through-via, the second substrate may be diced to separate the die stack from one or more other die stacks on the carrier substrate.

FIG. 4 is a block diagram illustrating a computer system 400, in accordance with some embodiments. In some embodiments, computer system 400 is connected (e.g., via a network, such as a Local Area Network (LAN), an intranet, an extranet, or the Internet) to other computer systems. In some embodiments, computer system 400 operates in the capacity of a server or a client computer in a client-server environment, or as a peer computer in a peer-to-peer or distributed network environment. In some embodiments, computer system 400 is provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 400 includes a processing device 402, a volatile memory 404 (e.g., Random Access Memory (RAM)), a non-volatile memory 406 (e.g., Read-Only Memory (ROM) or Electrically-Erasable Programmable ROM (EEPROM)), and a data storage device 416, which communicate with each other via a bus 408.

In some embodiments, processing device 402 is provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

In some embodiments, computer system 400 further includes a network interface device 422 (e.g., coupled to network 474). In some embodiments, computer system 400 also includes a video display unit 410 (e.g., an LCD), an alphanumeric input device 412 (e.g., a keyboard), a cursor control device 414 (e.g., a mouse), and a signal generation device 420.

In some implementations, data storage device 416 includes a non-transitory computer-readable storage medium 424 on which store instructions 426 encoding any one or more of the methods or functions described herein. For example, the instructions 426 can include instructions for controlling the movement of the stage and/or digital lithography exposure units (“exposure units”) of a digital lithography system, which, when executed, can implement the methods for performing exposure unit scan sequencing described herein.

In some embodiments, instructions 426 also reside, completely or partially, within volatile memory 404 and/or within processing device 402 during execution thereof by computer system 400, hence, in some embodiments, volatile memory 404 and processing device 402 also constitute machine-readable storage media.

While computer-readable storage medium 424 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

In some embodiments, the methods, components, and features described herein are implemented by discrete hardware components or are integrated in the functionality of other hardware components such as ASICS, FPGAs, DSPs or similar devices. In some embodiments, the methods, components, and features are implemented by firmware modules or functional circuitry within hardware devices. In some embodiments, the methods, components, and features are implemented in any combination of hardware devices and computer program components, or in computer programs.

Unless specifically stated otherwise, terms such as “training,” “identifying,” “further training,” “re-training,” “causing,” “receiving,” “providing,” “obtaining,” “optimizing,” “determining,” “updating,” “initializing,” “generating,” “adding,” “forming,” “stacking,” “testing,” “dicing,” “performing,” “depositing,” “patterning,” “filling,” “planarizing,” “bonding,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. In some embodiments, the terms “first,” “second,” “third,” “fourth,” etc. as used herein are meant as labels to distinguish among different elements and do not have an ordinal meaning according to their numerical designation.

Examples described herein also relate to an apparatus for performing the methods described herein. In some embodiments, this apparatus is specially constructed for performing the methods described herein, or includes a general purpose computer system selectively programmed by a computer program stored in the computer system. Such a computer program is stored in a computer-readable tangible storage medium.

The methods and illustrative examples described herein are not inherently related to any particular computer or other apparatus. In some embodiments, various general purpose systems are used in accordance with the teachings described herein. In some embodiments, a more specialized apparatus is constructed to perform methods described herein and/or each of their individual functions, routines, subroutines, or operations. Examples of the structure for a variety of these systems are set forth in the description above.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within +10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A method, comprising:
forming a plurality of dies on one or more first substrates;
stacking multiple dies of the plurality of dies on a second substrate to form a die stack; and
forming a through-via in the die stack, wherein the through-via electrically couples each of the multiple dies of the die stack.

2. The method of claim 1, further comprising:
testing each of the plurality of dies to identify a subset of the plurality of dies that meet a quality criterion, wherein the multiple dies that are stacked to form the die stack are selected from the subset of the plurality of dies.

3. The method of claim 1, further comprising:
dicing the one or more first substrates to separate the plurality of dies; and
performing a thinning operation with respect to the multiple dies, wherein the multiple dies are stacked after performance of the thinning operation.

4. The method of claim 1, further comprising:
stacking one or more additional die stacks on the die stack to form a multi-stack die stack, wherein each of the dies in the multi-stack die stack are electrically coupled by a through-via.

5. The method of claim 1, wherein each of the plurality of dies comprises a connective pad having a footprint larger than a diameter of the through-via, and wherein the through-via is formed through the connective pads of the multiple dies of the die stack.

6. The method of claim 1, further comprising:
depositing a mask layer on top of the die stack; and
patterning the mask layer to form a patterned mask layer, wherein the through-via is formed according to the patterned mask layer.

7. The method of claim 1, further comprising:
forming multiple die stacks on the second substrate, wherein each of the multiple die stacks are separated by one or more gaps;
filling the one or more gaps with a filler; and
planarizing the multiple die stacks and the filler to form a substantially planar top surface.

8. The method of claim 1, wherein the through-via is formed by performance of an anisotropic etch operation.

9. The method of claim 1, further comprising:
bonding the multiple dies of the die stack, wherein the multiple dies are bonded with a fusion bond.

10. A system, comprising:
a memory; and
a processing device operatively coupled with the memory, wherein the processing device is configured to:
cause a plurality of dies to be formed on one or more first substrates;
cause multiple dies of the plurality of dies to be stacked on a second substrate to form a die stack; and
cause a through-via to be formed in the die stack, wherein the through-via electrically couples each of the multiple dies of the die stack.

11. The system of claim 10, wherein the processing device is further configured to:
cause each of the plurality of dies to be tested to identify a subset of the plurality of dies that meet a quality criterion, wherein the multiple dies that are stacked to form the die stack are selected from the subset of the plurality of dies.

12. The system of claim 10, wherein the processing device is further configured to:
cause the one or more first substrates to be diced to separate the plurality of dies; and
cause a thinning operation to be performed with respect to the multiple dies, wherein the multiple dies are stacked after performance of the thinning operation.

13. The system of claim 10, wherein the processing device is further configured to:
cause one or more additional die stacks to be stacked on the die stack to form a multi-stack die stack, wherein each of the dies in the multi-stack die stack are electrically coupled by a through-via.

14. The system of claim 10, wherein the processing device is further configured to:
cause a mask layer to be deposited on top of the die stack; and
cause the mask layer to be patterned to form a patterned mask layer, wherein the through-via is formed according to the patterned mask layer.

15. The system of claim 10, wherein the processing device is further configured to:
cause multiple die stacks to be formed on the second substrate, wherein each of the multiple die stacks are separated by one or more gaps;
cause the one or more gaps to be filled with a filler; and
cause the multiple die stacks and the filler to be planarized to form a substantially planar top surface.

16. A manufacturing system, comprising:
one or more process tools, wherein the one or more process tools are configured to:
form a plurality of dies on one or more first substrates;
stack multiple dies of the plurality of dies on a second substrate to form a die stack; and
form a through-via in the die stack, wherein the through-via electrically couples each of the multiple dies of the die stack.

17. The manufacturing system of claim 16, wherein the one or more process tools are further configured to:
test each of the plurality of dies to identify a subset of the plurality of dies that meet a quality criterion, wherein the multiple dies that are stacked to form the die stack are selected from the subset of the plurality of dies.

18. The manufacturing system of claim 16, wherein the one or more process tools are further configured to:
dice the one or more first substrates to separate the plurality of dies; and
perform a thinning operation with respect to the multiple dies, wherein the multiple dies are stacked after performance of the thinning operation.

19. The manufacturing system of claim 16, wherein the one or more process tools are further configured to:
deposit a mask layer on top of the die stack; and
pattern the mask layer to form a patterned mask layer, wherein the through-via is formed according to the patterned mask layer.

20. The manufacturing system of claim 16, wherein the one or more process tools are further configured to:
form multiple die stacks on the second substrate, wherein each of the multiple die stacks are separated by one or more gaps;
fill the one or more gaps with a filler; and
planarize the multiple die stacks and the filler to form a substantially planar top surface.
